(19) United States
(12) Patent Application Publication
(10) Pub. No.: US 2002/0047217 A1
(43) Pub. Date: Apr. 25, 2002

(54) METALLIC UNDERCOATING FOR SOLDER MATERIALS

(76) Inventors: ELKE ZAKEL, SALKENSEE (DE); CHRISTINE KALLMAYER, BERLIN (DE); JENS NAVE, BERLIN (DE)

Correspondence Address: DOUGHERTY & CLEMENTS LLP, TWO FAIRVIEW CENTER, 6230 FAIRVIEW ROAD, SUITE 400, CHARLOTTE, NC, 28210, US

(21) Appl. No.: 09/325,494

(22) Filed: May 28, 1999

Related U.S. Application Data
(63) Continuation-in-part of application No. 08/913,387, filed on Jan. 20, 1998, now abandoned.
(63) Continuation of application No. PCT/DE96/00084, filed on Jan. 16, 1996.

(30) Foreign Application Priority Data
Mar. 1, 1995 (DE) 19507150.6
Aug. 2, 1995 (DE) 1952844.0

(51) Int. Cl. H01L 23/48

(52) U.S. Cl. 257/781

(57) ABSTRACT

A semiconductor substrate has an underbump metallization for solder materials. The semiconductor substrate has applied thereto a titanium layer serving as a diffusion barrier and as a wettable surface for the solder-material bump. The solder-material bump is adapted to be applied directly to said diffusion barrier.

### CROSS REFERENCE TO RELATED APPLICATION

This application is a Continuation-in-Part of U.S. patent application Ser. No. 08/913,387, filed August 27, 1997; which is a nationalization of PCT Application PCT/DE96/00084, dated Jan. 16, 1996.

### BACKGROUND OF THE INVENTION

1. Field of the Invention

The present invention refers to a semiconductor substrate with an underbump metallization for various solder materials.

2. Background Art

One pre condition for such a metallization is that it is easily wettable for the solder material to be applied and that it acts simultaneously as a diffusion barrier. and as a diffusion barrier. The material used for this purpose is titanium-tungsten which is applied by atomization or sputtering.

A disadvantage entailed by the use of such metallizations is that a further metallic layer consisting of copper, nickel, etc. has to be applied to the titanium-tungsten layer so as to provide a wettable base for the solder bumps or for die bonding. Another disadvantage is that the application of the second metallic layer results in the formation of brittle intermetallics with the solder material.

EP-A-0398485 discloses a solder material connection structure for components, which is provided with a metallization based on gold. The solder material connection structure comprises a semiconductor substrate having applied thereto a plurality of metallization layers; the layer applied directly to the substrate is a metal layer consisting of gold and having, in turn, applied thereto a layer of a material, such as titanium, which is inert with regard to the solder material and which has, in turn, arranged thereon a wettable connection surface. The solder material is applied to the wettable connection surface. The titanium layer, which is implemented as a barrier layer, must be non-wetting with regard to the solder material so that de-wetting can take place.

EP-A-0186585 refers to a chip connection process in the case of which a semiconductor substrate is provided with a barrier layer consisting of titanium and having subsequently applied thereto a connection layer of gold or silver.

EP-A-0186411 refers to a semiconductor element in which a semiconductor chip is connected to a base. The chip is connected to the substrate via a metal layer and a solder material. The metal layer can be a titanium layer.

EP-A-0253691 refers to a connection process for a silicon chip in the case of which an aluminum layer is arranged on the chip, said aluminum layer having provided thereon a barrier layer of titanium. The titanium layer has arranged thereon a tungsten layer. The solder material is applied to the tungsten layer.

JP-A-60-215585 refers to an airtight seal for a camera tube. A glass or ceramic component has applied thereto a titanium layer which has applied thereto a metallization layer of gold, tin or silver. This second layer has subsequently applied thereto the solder material.

JP-A-5-234632 refers to a conductive component and to the production of said component. An aluminum component is provided with layers of solder material on two opposed surfaces thereof, intermediate layers being formed between said layers and the aluminum body; one intermediate layer, which is arranged directly on said aluminum body, consists of titanium and the second intermediate layer is produced from copper or nickel.

JP-A-63-142638 refers to the production of a semiconductor component in which a semiconductor chip is metallized by titanium on the rear surface thereof and connected to a substrate by means of a solder material arranged on the titanium layer.

### OBJECTS OF THE INVENTION

It is the object of the present invention to provide a semiconductor substrate with an underbump metallization in the case of which the underbump metallization is easy to produce and can easily be wetted with the solder material to be applied.

It is also an object of this invention to provide a method of forming a semiconductor substrate with an underbump metallization in the case of which the underbump metallization is easy to produce and can easily be wetted with solder material to be applied.

### SUMMARY OF THE INVENTION

The present invention is a semiconductor substrate base which is provided with an underbump metallization for solder materials. The semiconductor substrate base has applied thereto an aluminum connection layer, which has directly applied thereto a titanium diffusion barrier serving as a diffusion barrier and as a wettable surface for the solder-material bump. The solder-material bump is adapted to be applied directly to said diffusion barrier.

In comparison with the prior art described hereinbefore, the present invention offers the advantage that no second metallic layer is required for obtaining a good wettability with a solder material, whereby the production method for such metallic undercoatings is substantially simplified.

Another advantage is to be seen in the fact that by avoiding the second metallic layer the formation of brittle intermetallics is prevented.

### BRIEF DESCRIPTION OF THE DRAWINGS

The foregoing and other objects will become more readily apparent by referring to the following detailed description and the appended drawings in which:

FIG. 1 shows a first embodiment of a substrate base provided with a metallic undercoating and a solder depot according to the present invention;

FIG. 2 shows a second embodiment of a substrate base provided with a metallic undercoating and a solder depot according to the present invention; and

FIG. 3 shows a third embodiment of a substrate base provided with a metallic undercoating and a solder de pot according to the present invention.

### DESCRIPTION OF PREFERRED EMBODIMENTS

In the description of the present invention following herein below, elements which are identical in the various drawings are designated by identical reference numerals.

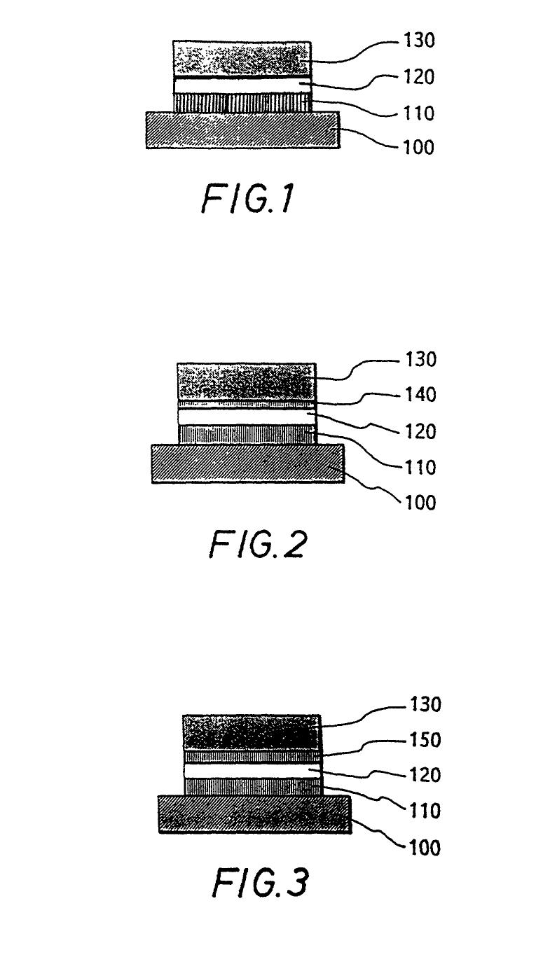

FIG. 1 shows a first embodiment of the present invention. A substrate base 100 has arranged thereon a connection layer 110 on which a titanium diffusion barrier 120 is arranged. This titanium diffusion barrier 120 forms a metallic undercoating for a solder 130 to be applied to this titanium diffusion barrier 120.

The titanium diffusion barrier 120 offers a wettable basis for various solder materials 130. Possible solder materials include: lead alloys, silver alloys, tin alloys, gold alloys, bismuth alloys, antimony alloys, indium, and indium alloys. More specific examples include: Pb/Sn, Au/Sn, In solders, Sn/Ag, and Sn/Bi.

Possible solder application methods are mechanical and galvanic bumping, dip soldering and vapor deposition.

The metallic undercoating according to the present invention is, however, not limited to solder application methods of this type, but it is also adapted to be used for what is termed die bonding.

In the embodiment shown in FIG. 1, only one step is required for applying the metallic undercoating during a production process of component to which solder materials are to be applied.

Prior to applying the solder material 130 to the titanium diffusion barrier 120, an oxide layer must be removed from the titanium diffusion barrier 120, such oxide layer forming on the titanium diffusion barrier when the production process is carried out in normal surroundings.

The formation of an oxide layer on the titanium diffusion barrier 120 can, however, be avoided when the production process is carried out in a vacuum.

The metal layer 110 can be made from aluminum or gold for example.

The second embodiment shown in FIG. 2 corresponds essentially to the embodiment according to FIG. 1. It includes, however, a metal layer 140, such as gold, which is arranged between the titanium diffusion barrier 120 and the solder material 130.

Due to the fact that titanium has a strong affinity for gold, it forms various so-called intermetallics with gold. These intermetallics are easily wettable by various solder materials.

Possible solder materials have already been described on the basis of embodiment 1 in FIG. 1.

Due to the use of the metal layer 140, oxidation of the titanium diffusion barrier 120 is avoided during a production process of the metallic undercoating. The layer 140 is not limited to gold, but any other metal having a sufficient affinity for titanium is just as suitable to be used as said layer 140. These metals include: silver, silver alloys, platinum, palladium, titanium-aluminum alloys, nickel-aluminum alloys, titanium-nickel-aluminum alloys, titanium-nitrogen alloys, and titanium-niobium alloys.

The embodiment shown in FIG. 3 corresponds essentially to FIG. 2 with the exception that the titanium diffusion barrier 120 and the solder material 130 have arranged between them a metallic layer 150 instead of the metal layer 140.

Titanium forms various intermetallics with tin so that a good wettability for solder materials exists again.

During the production process, an oxide layer forms on the metallic layer 150, and this oxide layer has to be removed prior to applying the solder material 130. Possible methods for removing this oxide layer and for removing an oxide layer which formed directly on the titanium diffusion barrier 120 (as in the first embodiment) include mechanical methods, such as ultrasonic methods, chemical methods, such as plasma etching, and physical methods, such as sputter etching.

Reference is made to the fact that possible materials for the layer 150 are not limited to tin, but that any other solder material having corresponding properties is suitable to be used in said layer 150. These materials include: lead, lead alloys, silver, silver alloys, gold, gold alloys, antimony containing solders, bismuth containing solders, indium, and indium alloys.

Furthermore, it is emphasized that the layers 110 to 150 shown in the embodiments described hereinbefore can be produced by deposition processes which are known per se or by other methods hereinbefore can be produced by deposition processes which are known per se or by other methods of applying layers.

In all the above-mentioned embodiments of the present invention, the titanium layer 120 acts as a diffusion barrier and as a wettable surface for the solid material bump.

### SUMMARY OF THE ACHIEVEMENT OF THE OBJECTS OF THE INVENTION

From the foregoing, it is readily apparent that we have invented an improved semiconductor substrate with an underbump metallization in the case of which the underbump metallization is easy to produce and can easily be wetted with the solder material. We have also invented a method for forming an improved semiconductor substrate.

It is to be understood that the foregoing description and specific embodiments are merely illustrative of the best mode of the invention and the principles thereof, and that various modifications and additions may be made by those skilled in the art, without departing from the spirit and scope of this invention, which is therefore understood to be limited only by the scope of the appended claims.

What we claim is:

1. A semiconductor substrate comprising:
a base;
a connection layer applied to said base;
a titanium diffusion barrier layer directly applied to said connection layer; and
a solder material bump applied directly to said diffusion barrier;
wherein said diffusion barrier acts as a wettable surface for the solder-material bump.

2. A semiconductor substrate according to claim 1 wherein said connection layer is selected from the group consisting of aluminum and gold.

3. A semiconductor substrate according to claim 1 wherein the solder-material bump is selected from the group consisting of: lead alloys, silver alloys, tin alloys, gold alloys, bismuth alloys, antimony alloys, indium, and indium alloys.

4. A semiconductor substrate according to claim 3 wherein the solder-material bump is selected from the group consisting of: lead-tin alloys, gold-tin alloys, tin-silver alloys, tin-bismuth alloys, and indium alloys.

5. A semiconductor substrate according to claim 1 further comprising a metal layer between said diffusion barrier and said solder-material bumps, said metal layer being selected from the group consisting of metals and alloys that have a strong affinity for titanium and form intermetallics with titanium which are readily wettable by solders.

6. A semiconductor substrate according to claim 5 wherein the metal layer is selected from the group consisting of: gold, silver, platinum, palladium, and alloys thereof, titanium-aluminum alloys, nickel-aluminum alloys, titanium-nickel-aluminum alloys, titanium-nitrogen alloys, and titanium-niobium alloys.

7. A semiconductor substrate according to claim 5 wherein the metal layer is tin.

8. A method of forming a semiconductor substrate comprising:
providing a base;
forming a connection layer on the surface of the base;
applying a titanium diffusion barrier layer directly to the surface of the connection layer; and
applying a solder material bump directly to said diffusion barrier;
wherein said method is carried out in a vacuum.

9. A method according to claim 8, further comprising applying a metal layer between said diffusion barrier layer and said solder material bump.

10. A method of forming a semiconductor substrate comprising:
providing a base;
forming a connection layer on the surface of the base;
applying a titanium diffusion barrier layer directly to the surface of the connection layer;
removing any oxide layers from the connection layer by any of mechanical, chemical, or physical methods; and
applying a solder material bump directly to the diffusion barrier.

11. A method according to claim 10, wherein said mechanical oxide removing method is ultrasonic methods.

12. A method according to claim 10, wherein said chemical oxide removing method is plasma etching.

13. A method according to claim 10, wherein said physical oxide removing method is sputter etching.

14. A method according to claim 10, further comprising applying a metal layer between said diffusion barrier layer and said solder material bump.
